(19) United States
(12) Patent Application Publication
(10) Pub. No.: US 2011/0169580 A1
(43) Pub. Date: Jul. 14, 2011

(54) INVERTING GATE WITH MAXIMIZED THERMAL NOISE IN RANDOM NUMBER GENERTION

(76) Inventor: James Dodrill, Dripping Springs, TX (US)

(21) Appl. No.: 12/957,271

(22) Filed: Nov. 30, 2010

Related U.S. Application Data
(60) Provisional application No. 61/293,410, filed on Jan. 8, 2010.

(51) Int. Cl. H03B 1/00; H03K 3/03

(52) U.S. Cl. 331/56; 331/57

(57) ABSTRACT

A random number generator comprises a first high frequency (HF) oscillator, a second low frequency (LF) oscillator, and a sampling circuit. The HF oscillator generates a high frequency oscillating signal. The LF oscillator generates a low frequency oscillating signal. The LF oscillating signal is used to sample the HF oscillating signal to generate a sequence of random bits. In one preferred embodiment, the LF oscillator comprises a plurality of stages of inverters, and each inverter comprises a number of series-stacked minimum length transistors. The LF oscillating signal has a jitter distribution due to thermal noise present in each transistor of the LF oscillator. By series stacking a number of minimum length transistors in each inverter, the overall thermal noise in the LF oscillator is maximized to increase the jitter distribution of the LF oscillating signal and thereby increase the random behavior of the sequence of random bits.

### CROSS REFERENCE TO RELATED APPLICATIONS

This application claims priority under 35 U.S.C. §119 from U.S. Provisional Application No. 61/293,410, entitled “Inverting Gate with Maximized Thermal Noise for Use in Random Number Generation,” filed on Jan. 8, 2010, the subject matter of which is incorporated herein by reference.

### TECHNICAL FIELD

The present invention relates generally to random number generator, and, more particularly, to maximizing thermal noise in random number generation.

### BACKGROUND

A random number generator is a physical or computational device designed to generate a sequence of numbers or symbols that lack any pattern. Random number generators are often used in applications such as gambling, statistical sampling, computer simulation, cryptography, completely randomized design, and other areas where producing an unpredictable result is desirable. In general, when unpredictability is paramount, such as in security-related applications, hardware generators are generally preferred over pseudo-random algorithms. A hardware random number generator is based on measurements on some physical phenomenon that is expected to be truly random. For example, true random sources include radioactive decay, thermal noise, shot noise, avalanche noise in Zener diodes, and radio noise. If a stochastic source of randomness can be sufficiently isolated from all deterministic influences, then a truly random number generator can be realized. In complementary metal-oxide-semiconductor (CMOS) technology, one common random number generating technique involves the use of timing jitter found in ring oscillators as a source of randomness. Timing jitter is a stochastic phenomenon caused by thermal noise present in the transistors of a ring oscillator. Because thermal noise is a true random source, two or more oscillators can be combined to produce a sequence of true random bit stream.

FIG. 1 (Prior Art) illustrates a conventional random number generator (RNG) 10. RNG 10 comprises a high frequency (HF) oscillator 11, a low frequency (LF) oscillator 12, and a D-type flip-flop (DFF) 13. HF oscillator 11 generates a high frequency oscillating signal 14, which provides an input signal for DFF 13. LF oscillator 12 generates a low frequency oscillating signal 15, which provides a clock signal for DFF 13. Thus, DFF 13 samples high frequency oscillating signal 14 at a low frequency determined by clock signal 15 and outputs a bit steam 16. If the frequency of the LF oscillator randomly drifts with each cycle (jitter), then output bit stream 16 would be random.

In the example of FIG. 1, LF oscillator 12 is a ring oscillator comprising a number of inverting stages. Each inverter (i.e., inverter 17) comprises a P-channel field effect transistor (PFET) 18 and an N-channel field effect transistor (NFET) 19. Due to thermal noise present in the transistors, clock signal 15 has some jitter and its frequency randomly drifts from cycle to cycle. Such jitter causes the drift of phase relationship between HF oscillator 11 and LF oscillator 12, which in turn provides some random behavior of output bit stream 16. It has been reported, however, that sufficient randomness cannot be achieved under this technique. Improvement is sought to achieve better results.

### SUMMARY

A random number generator comprises a first high frequency (HF) oscillator, a second low frequency (LF) oscillator, and a sampling circuit. The HF oscillator generates a high frequency oscillating signal. The LF oscillator generates a low frequency oscillating signal. The LF oscillating signal is used to sample the HF oscillating signal to generate a sequence of random bits. The LF oscillator comprises a plurality of stages of inverters, and each inverter comprises a number of series-stacked minimum length transistors. The LF oscillating signal has a jitter distribution due to thermal noise present in each transistor of the LF oscillator. By series stacking a number of minimum length transistors in each inverter, the overall thermal noise in the LF oscillator is maximized to increase the jitter distribution of the LF oscillating signal and thereby increase the random behavior of the sequence of random bits.

In one preferred embodiment, the LF oscillator comprises approximately one hundred and five stages of inverters for generating the sequence of random bits at a rate of approximately 1 MHz. Each inverter comprises approximately twenty series-stacked minimum length transistors. Maximum thermal noise and jitter is achieved via the use of the number of stacked-gate inverters. First, slow transition times are achieved by decreasing the drive strength and increasing the load capacitance of the stacked-gate inverters. Slower edge-rates keep the inverters in their active region longer such that thermal noise has more time to introduce jitter onto the LF ring oscillator. Second, by using minimum channel length for each of the series-stacked transistors, the thermal noise generated by each individual transistor is maximized. In addition, the thermal noise currents flowing across all the series-stacked transistors are accumulated to increase the overall thermal noise current. Third, by stacking transistors in series, many of the stacked transistors in the stack have reduced gate to source voltage (V_{GS}) during their active transition time, which also maximizes thermal noise. The novel stacked-gate inverter is easy to design and use.

Other embodiments and advantages are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 (Prior Art) illustrates a conventional random number generator.

FIG. 2 is a simplified block diagram of a random number generator in accordance with one novel aspect.

FIG. 3 is a circuit and waveform diagram of a low frequency ring oscillator comprising inverter with stacked gates in accordance with one novel aspect.

FIG. 4 is a diagram that illustrates jitter vs. number of stages of inverters.

FIG. 5 is a diagram that illustrates jitter of thirty inverters vs. channel length L.

FIG. 6 is a diagram that illustrates jitter of thirty stacked-gate inverters vs. stack height.

FIG. 7 is a diagram that illustrates simulation result of jitter in accordance with one novel aspect.

FIG. 8 is a layout diagram of a stacked-gate inverter within a low frequency ring oscillator.

FIG. 9 is a flow chart of a method of maximizing thermal noise for random number generation in accordance of one novel aspect.

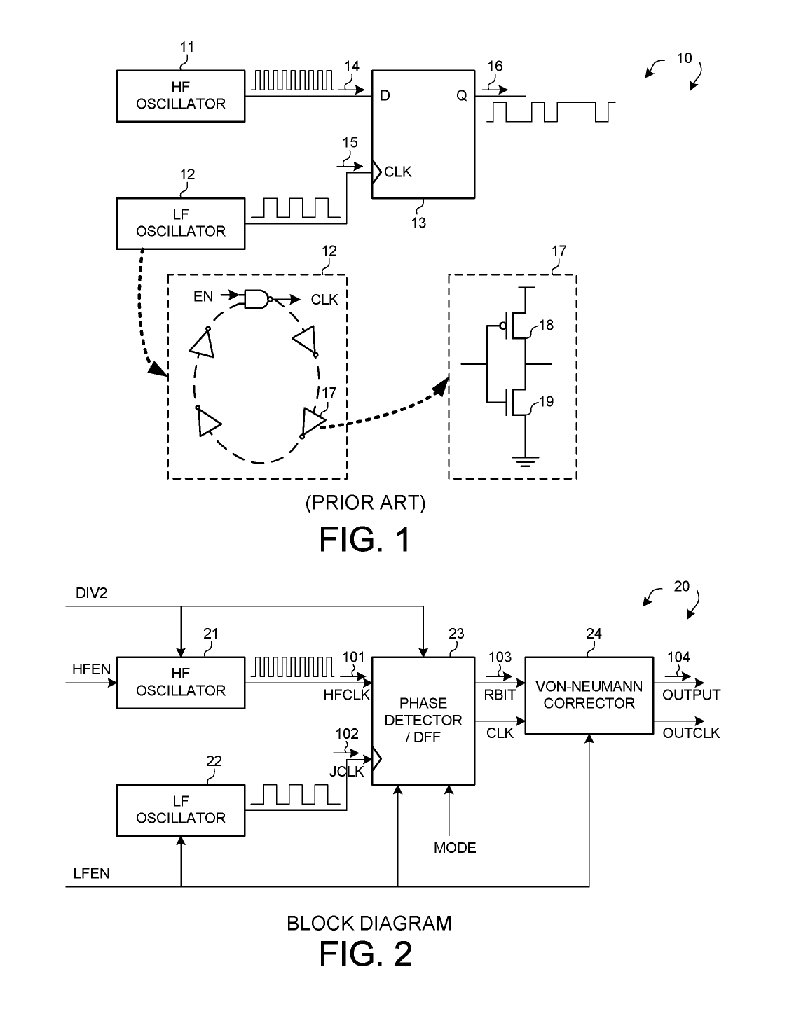

### DETAILED DESCRIPTION

Reference will now be made in detail to some embodiments of the invention, examples of which are illustrated in the accompanying drawings.

FIG. 2 is a simplified block diagram of a random number generator 20 in accordance with one novel aspect. Random number generator 20 comprises a high frequency (HF) oscillator 21, a low frequency (LF) oscillator 22, a phase detector (PD) or D-type flip-flop (DFF) 23, and a Von-Neumann corrector 24. HF oscillator 21 receives an enable signal HFEN that enables the HF oscillator to generate a high frequency oscillating signal HFCLK 101. LF oscillator 22 receives another enable signal LFEN that enables the LF oscillator to generate a low frequency oscillating signal JCLK 102 (also referred to as the jitter clock). Enable signal LFEN also controls the enabling/disabling of PD/DFF 23 and Von-Neumann corrector 24. PD/DFF 23 samples HFCLK 101 using JCLK 102 and outputs a random bit stream REIT 103 and clock signal CLK. PD/DFF 23 is controlled by a mode signal MODE to switch between a phase detector and a D-type flip-flop. In addition, a divide-by-two control signal DIV2 is optionally used to reduce the high frequency oscillating speed of HFCLK 101 should radio frequency noise interfere with unrelated radio. Ideally, REIT 103 is a random bit stream having truly randomized digital values of LOW (“0”) or HIGH (“1”). To balance the number of LOWs and HIGHs, RBIT 103 and CLK are supplied onto Von-Neumann corrector 24, which generates an output bit stream OUTPUT 104 and an output clock signal OUTCLK. Von-Neumann corrector 24 outputs the final random bit stream OUTPUT 104 by removing all 0/1 biases in random bit stream RBIT 103.

It is well known in the art that timing jitter found in CMOS ring oscillators can be used as a source of true randomness. Timing jitter is a stochastic phenomenon caused by channel thermal noise present in the transistors of a ring oscillator. In the example of FIG. 2, LF oscillator 22 is a ring oscillator comprising a plurality of inverting stages. Each inverting stage is formed by an inverter comprising a number of series-stacked transistors. In one novel aspect, by using a plurality of stacked-gate inverters, thermal noise in LF oscillator 22 is maximized to increase the jitter distribution of jitter clock JCLK 102 generated by LF oscillator 22 and thereby ensuring true random behavior of RBIT 103.

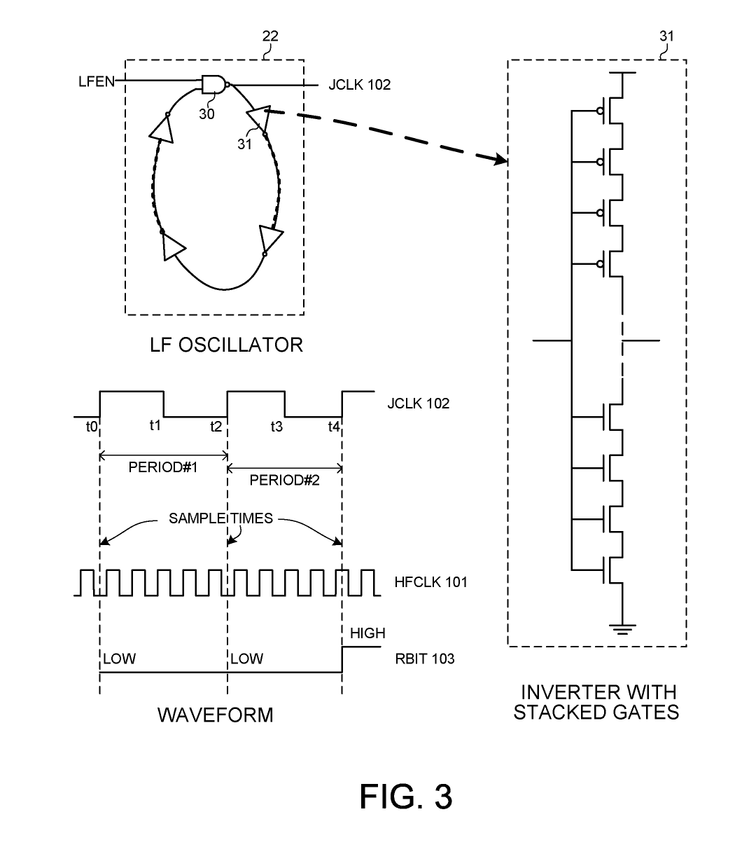

FIG. 3 is a circuit and waveform diagram of LF ring oscillator 22 in accordance with one novel aspect. LF ring oscillator 22 comprises a NAND gate 30 and a plurality of inverters including inverter 31. Inverter 31 comprises a number of series-stacked P-channel metal-oxide-semiconductor filed-effect transistors (MOSFETs) and N-channel MOSFETs. When the total number of inverting stages in LF ring oscillator 22 is an odd number, LF ring oscillator 22 generates an oscillating signal JCLK 102, as illustrated in FIG. 3. Due to the thermal noise present in each of the MOSFETs in each inverter, the oscillating period of JCLK 102 drifts randomly from cycle to cycle resulting in a jitter distribution of the oscillating frequency of JCLK 102. In the example of FIG. 3, a first oscillating period#1=t2−t0 is different from a second oscillating period#2=t4−t2.

To generate random bit stream REIT 103, each low-to-high rising edge (or alternatively, each high-to-low falling edge) of JCLK 102 is used to sample a much higher frequency oscillating signal HFCLK 101 generated by HF oscillator 21. For example, HFCLK 101 is sampled at various transition time instants t0, t2, and t4. At time t0, the sampled value of HFCLK 101 is a digital LOW (“0”); at time t2, the sampled value of HFCLK 101 is also a digital LOW (“0”); and at time t4, the sampled value of HFCLK 101 is a digital HIGH (“1”). Therefore, the timing jitter of JCLK 102 causes the phase relation between HFCLK 101 and JCLK 102 to drift randomly, resulting in a random bit stream RBIT 103.

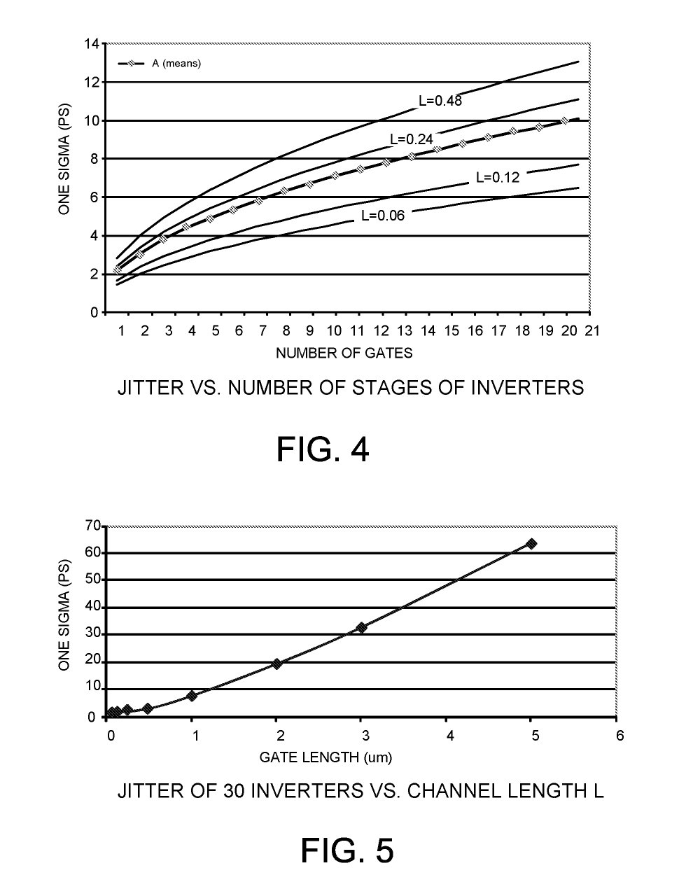

In general, the random behavior of RBIT 103 depends on the jitter distribution of JCLK 102 generated from the LF ring oscillator 22. The jitter distribution of JCLK 102 in turn depends on the number of inverters as well as the thermal noise performance of the MOSFETs in each inverter used in LF ring oscillator 22 in CMOS semi-conductor technology. FIG. 4 is a diagram that illustrates jitter vs. number of stages of inverters. As illustrated in FIG. 4, the accumulation of jitter is proportional to the square root of the number of inverting (delay) stages in a ring oscillator:

jitter∝\sqrt{n} (1)

where n is the number of inverting (delay) stages in the ring oscillator. It can be seen, that with a fixed channel length, the jitter in one-sigma increases proportionally to the square root of n.

The number of inverting stages, however, should not be increased without limit. The more inverters added onto the ring oscillator, the slower oscillating frequency is generated. In addition, the accumulation of jitter does not lineally increase as n increases. As a result, when n gets larger and larger, each additional inverting stage becomes less and less effective. In one embodiment, the number of inverting stages n in LF ring oscillator 22 is chosen to be one hundred and five (n=105) to generate a one MHz target oscillating frequency for jitter clock JCLK 102.

Because the jitter distribution of JCLK 102 cannot be increased as desired by increasing the number of delay inverters, it becomes more critical to be able to increase the thermal noise performance of the MOSFETs in each inverter. In one novel aspect, a number of series-stacked minimum-length P-channel MOSFETs and N-channel MOSFETs are used to make each inverter (e.g., inverter 31 in FIG. 3) in LF ring oscillator 22 to maximize thermal noise and thereby increasing jitter distribution of JCLK 102. The novel design of using series-stacked minimum-length transistors in each inverter has several advantages in maximizing the overall thermal noise. During the design process of the novel inverter, three different factors were exploited to increase the thermal noise and jitter of the inverter.

First, the inverting gates making up the LF ring oscillator have slow transition times (i.e., slow edge-rates) so that the gates are in their active region for a relatively long time to increase jitter. This is because during the active region, the current variations caused by channel thermal noise are translated into the time delay variations. As a result, slower edge-rates keep the inverters in their active region longer, and channel thermal noise thus has more time to introduce jitter onto the LF ring oscillator. The edge-rate of a CMOS inverting gate is determined by two factors based on the following equation:

$$EdgeRate ∝ [ \frac{\frac{1}{W}}{{L}_{eff}} , {C}_{LOAD} ] \qquad ( 2 )$$

where W is the channel width, L_{eff} is the effective channel length, W/L is the channel ratio of the transistors (W/L_{eff} typically indicates the drive strength of the inverter), and C_{LOAD} is the load capacitance that the inverter is driving. Thus, in order to have slower edge-rates for increased jitter, it is desirable to have small W/L_{eff} channel ratio and high load capacitance. FIG. 5 is a diagram that illustrates the jitter distribution of a 30-inverter LF oscillator vs. channel length L. As illustrated in FIG. 5, longer channel length L, slows down edge-rates and leads to increased jitter, almost linearly.

Second, channel thermal noise is inversely proportional to the effective channel length squared as illustrated by the following equation:

$${S}_{{id}^{2}} = \frac{4 kT}{{L}_{eff}^{2}} {μ}_{eff} \vert {Q}_{inv} \vert \qquad ( 3 )$$

where S is the power spectral density of the channel thermal noise, k is the Boltzmann's constant, T is the lattice temperature, L_{eff} is the effective channel length, μ_{eff} is the effective mobility, Qᵢₙᵥ is the total inversion layer charge. Based on Equation (3), short channel transistors create more noise than long channel transistors.

Third, in deep sub-micron technologies, minimizing V_{GS} (the voltage between a transistor's gate terminal and source terminal) increases the thermal noise of the transistor. Small V_{GS} helps the transistor to stay in linear region without going into saturation region and thus helps increasing thermal noise current during its active transition time.

By combining the above-illustrated three factors together, it can be seen that the novel series-stacked minimum-gate inverter 31 in FIG. 3 accomplishes all three objectives in maximizing thermal noise and thereby increasing jitter distribution of JCLK 102. First, slow transition times are achieved by decreasing the drive strength and increasing the load capacitance of each inverter. Although each transistor has a minimum channel length L, the effective channel length L_{eff} for each inverter is the summation of the channel lengths of all the series-stacked transistors in terms of the drive strength of each inverter (i.e., L_{eff}=ΣL). Thus, the drive strength of each inverter is effectively decreased with reduced W/L_{eff} ratio. In addition, the load capacitance C_{LOAD} is naturally increased because each inverter has to drive an increased number of series-stacked gates. Second, by using minimum channel length for each of the series-stacked transistors, the thermal noise generated by each individual transistor is maximized. In addition, the thermal noise currents flowing across all the series-stacked transistors are accumulated to increase the overall thermal noise current. Third, by stacking transistors in series, many of the stacked transistors in the stack have reduced V_{GS} during their active transition time. When transistors are stacked in series, the drain to source voltage V_{DS} of each transistor is small because it is distributed across the entire stack. Small V_{DS} helps to float the gates and to minimize V_{GS} and thereby increase thermal noise due to the velocity saturation effect.

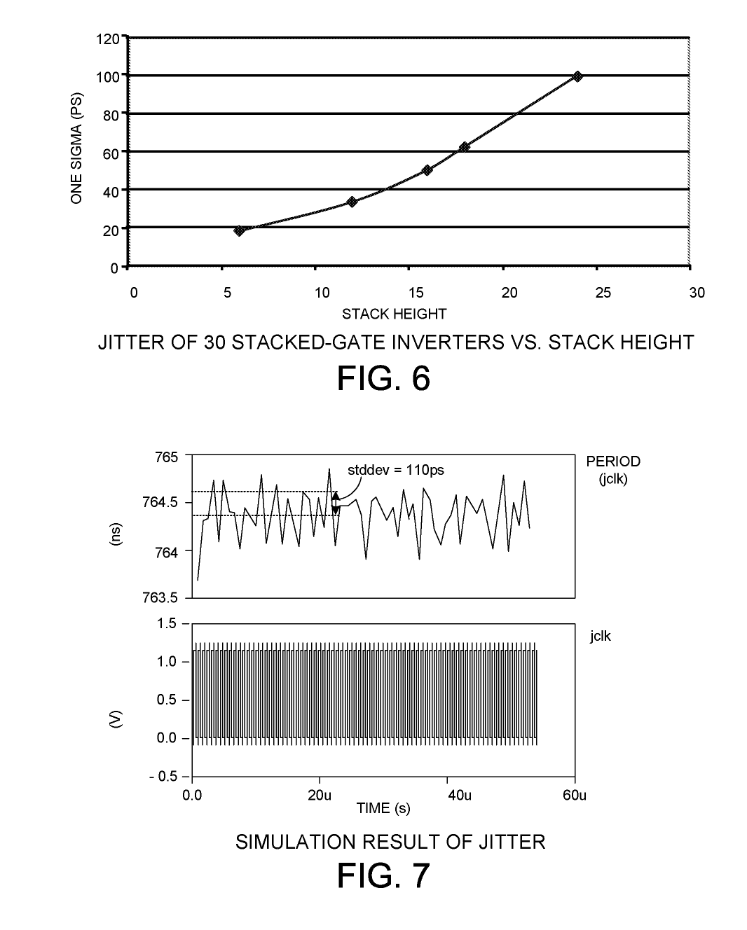

FIG. 6 is a diagram that illustrates jitter of thirty stacked-gate inverters vs. stack height. In the example of FIG. 6, the vertical axis represents the jitter in one-sigma of an oscillating signal generated by a ring oscillator with thirty inverters (plus one NAND gate), while the horizontal axis represents the stack height (i.e., the number of stacked transistors h) of each of the inverters used in the ring oscillator. It can be seen that the jitter increases almost linearly with the increase of the stack height h. In one preferred embodiment, about twenty (h=20) transistors are series-stacked to form each inverter of an LF ring oscillator.

FIG. 7 is a diagram that illustrates simulation result of jitter of an LF oscillating signal JCLK in accordance with one novel aspect. The bottom part of FIG. 7 is the waveform of the LF oscillating jitter clock signal JCLK generated by an LF ring oscillator that comprises a plurality of stacked-gate inverters. The top part of FIG. 7 is the measurement of each individual PERIOD corresponding to each oscillating cycle of JCLK. Based on the PERIOD measurement values of JCLK, the jitter distribution of JCLK can be derived by calculating the standard deviation of PERIOD. As illustrated in FIG. 7, the standard deviation of PERIOD reaches 110 ps to 130 ps.

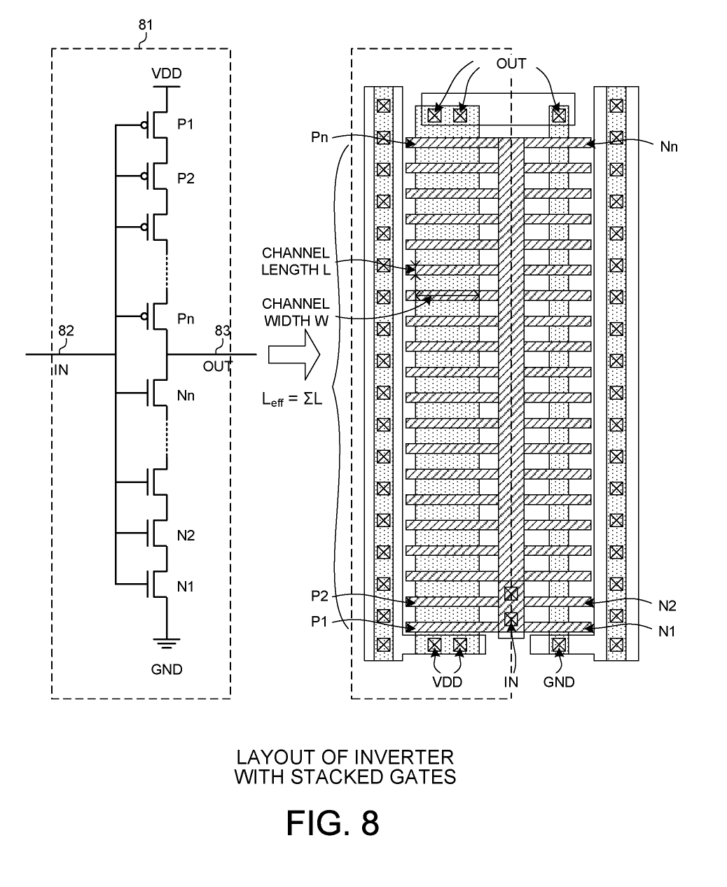

FIG. 8 illustrates a circuit and corresponding layout diagram of a stacked-gate inverter 81 within an LF ring oscillator. As depicted by the left part of FIG. 8, stacked-gate inverter 81 comprises a number of P-channel MOSFETs P1, P2 . . . and Pn, as well as a number of N-channel MOSFETs N1, N2 . . . and Nn. The gates of all the transistors are connected together, while the source and drain of transistors P1, P2 . . . Pn and N1, N2 . . . Nn are series-stacked one by one from VDD to GND. In addition, the gates are connected to input node IN82, and transistors Pn and Nn are connected to output node OUT83. As depicted by the right part of FIG. 8, the corresponding layout of stacked-gate inverter 81 is straightforward. P-channel and N-channel transistors are arranged side-by-side as pairs and extended along the channel length direction. In this example in a 65 nm semiconductor process technology, the drawn P-channel transistor Width/Length sizes are 450 nm/60 nm and the drawn N-channel transistor Width/Length sizes are 150 nm/60 nm. Thus, the channel lengths L of the transistors are the minimum allowed by the semiconductor process to maximize the thermal noise for each individual transistor. On the other hand, the effective channel length (L_{eff}=ΣL) of inverter 81 is much longer to slow down its transition time by summing all the individual channel lengths together. As illustrated in FIG. 8, the novel stacked-gate inverter 81 is easy to design and use from both circuit and layout point of view.

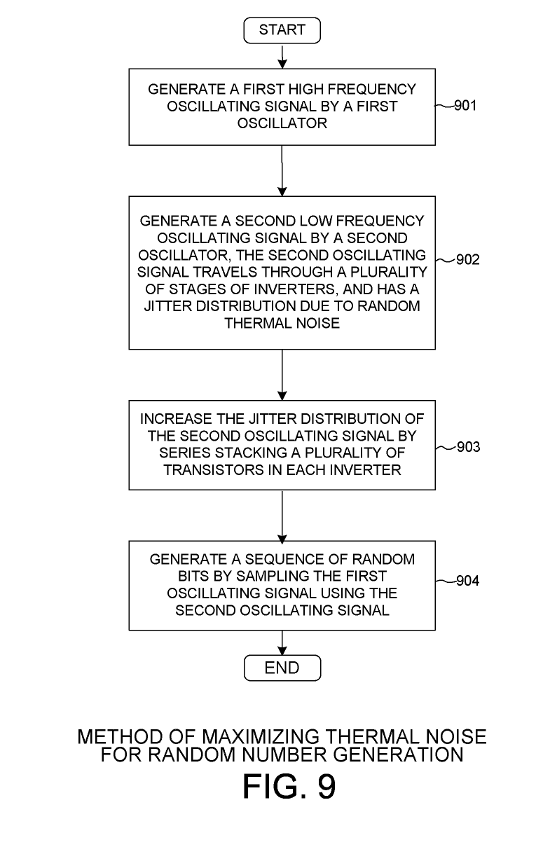

FIG. 9 is a flow chart of a method of maximizing thermal noise for random number generation in accordance of one novel aspect. In step 901, a first high frequency (HF) oscillating signal is generated by a first HF ring oscillator. In step 902, a second low frequency (LF) oscillating signal is generated by a second LF ring oscillator comprising a plurality of inverting stages. The second LF oscillating signal has a jitter distribution due to random thermal noise present in the CMOS transistors in each of the inverting gate of the LF ring oscillator. In step 903, the jitter distribution of the second LF oscillating signal is increased by series stacking a number of minimum length transistors in each inverter. Finally, in step 904, the second LF oscillating signal is used to sample the first HF oscillating signal to output a sequence of random bit stream. The increased jitter of the second LF oscillating signal ensures sufficient randomness of the output bit stream.

Although the present invention has been described in connection with certain specific embodiments for instructional purposes, the present invention is not limited thereto. Accordingly, various modifications, adaptations, and combinations of various features of the described embodiments can be practiced without departing from the scope of the invention as set forth in the claims.

What is claimed is:

1. A random number generator, comprising:
a first oscillator that outputs a high frequency oscillating signal;
a second oscillator that outputs a low frequency oscillating signal, wherein the second oscillator comprises a plurality of stages of inverters, wherein each inverter comprises a plurality of series-stacked transistors, and wherein the low frequency oscillating signal has a jitter distribution due to random thermal noise in each transistor; and
a sampling circuit that samples the high frequency oscillating signal using the low frequency oscillating signal, and in response generates a sequence of random bits.

2. The random number generator of claim 1, wherein the second oscillator has approximately one hundred and five stages of inverters for generating the sequence of random bits at a rate of approximately 1 MHz.

3. The random number generator of claim 1, wherein each inverter has approximately twenty series-stacked minimum-length transistors.

4. The random number generator of claim 1, wherein each transistor in each inverter has minimum gate length to increase the random thermal noise of each transistor and thereby increase the jitter distribution of the low frequency oscillating signal.

5. The random number generator of claim 1, wherein many series-stacked transistors in each inverter have reduced gate-to-source voltage resulting in increased jitter distribution of the low frequency oscillating signal.

6. The random number generator of claim 1, wherein each inverter has a slower transition time due to the series-stacked transistor resulting in increased jitter distribution of the low frequency oscillating signal.

7. The random number generator of claim 1, wherein the sampling circuitry is either a phase detector or a D-type Flip-Flop.

8. The random number generator of claim 1, wherein the random generator further comprises a corrector for assuring the sequence of random bits has approximately equal number of zeros and ones on average.

9. A method for generating a sequence of random bits, comprising:
generating a first high frequency oscillating signal by a first oscillator;
generating a second low frequency oscillating signal by a second oscillator, wherein the second oscillating signal travels through a plurality of stages of inverters, wherein each inverter has a plurality of series-stacked transistors, and wherein the second oscillating signal has a jitter distribution due to random thermal noise present in each of the transistors;
increasing the jitter distribution of the second oscillating signal by series stacking a plurality of transistors in each inverter; and
generating a sequence of random bits by sampling the first oscillating signal using the second oscillating signal.

10. The method of claim 9, wherein the second oscillating signal travels through approximately one hundred and five stages of inverters for generating the sequence of random bits at a rate of approximately 1 MHz.

11. The method of claim 9, wherein each inverter has approximately twenty series-stacked minimum-length transistors.

12. The method of claim 9, wherein each transistor in each inverter has minimum gate length to increase the random thermal noise of each transistor and thereby increase the jitter distribution of the low frequency oscillating signal.

13. The method of claim 9, wherein many series-stacked transistors in each inverter have reduced gate-to-source voltage resulting in increased jitter distribution of the low frequency oscillating signal.

14. The method of claim 9, wherein each inverter has a slower transition time due to the series-stacked transistor resulting in increased jitter distribution of the low frequency oscillating signal.

15. The method of claim 9, wherein the sampling involves the use of either a phase detector or a D-type Flip-Flop.

16. The method of claim 9, wherein the sequence of random bits is corrected to have approximately equal number of zeros and ones on average.

17. A ring oscillator, comprising:
an input node that receives an enable signal;
a plurality of series-connected inverters to form the ring oscillator, each inverter comprises a plurality of series-stacked transistors; and
an output node that generates an oscillating clock signal when enabled by the enable signal, wherein the oscillating clock signal has a jitter distribution due to thermal noise present in each of the transistors, and wherein the terminal noise is a true random source.

18. The ring oscillator of claim 17, wherein each transistor in each inverter has minimum gate length to increase the random thermal noise of each transistor and thereby increase the jitter distribution of the oscillating clock signal.

19. The ring oscillator of claim 17, wherein many series-stacked transistors in each inverter have reduced gate-to-source voltage resulting in increased jitter distribution of the oscillating clock signal.

20. The ring oscillator of claim 17, wherein each inverter has a slower transition time due to the series-stacked transistor resulting in increased jitter distribution of the oscillating clock signal.
